(19) United States
(12) Patent Application Publication
(10) Pub. No.: US 2006/0130894 A1
(43) Pub. Date: Jun. 22, 2006

(54) Illumination devices and methods of making the same

(76) Inventors: John Yupeng Gui, Niskayuna, NY (US); Anil Raj Duggal, Niskayuna, NY (US); Jeffrey Joseph Popielarczyk, Clifton Park, NY (US)

Correspondence Address: Patrick S. Yoder;FLETCHER YODER, P.O. Box 692289, Houston, TX, 77269-2289, US

(21) Appl. No.: 11/021,494

(22) Filed: Dec. 22, 2004

(51) Int. Cl. H01L 31/00

(52) U.S. Cl. 136/263; 136/252

(57) ABSTRACT

An illumination device includes a photovoltaic element, wherein the photovoltaic element is configured to absorb photons of desired wavelengths and to convert the absorbed photon energy to electric energy and an electroluminescence element disposed adjacent to the photovoltaic element, wherein the electroluminescence element is configured to produce illumination at desired wavelengths, and wherein at least one of the photovoltaic element or the electroluminescence element comprises an organic device. The illumination device also includes an electric energy storage element coupled to the photovoltaic element and to the electroluminescence element, wherein the electric energy storage element is configured to store electric energy from the photovoltaic element and to power the electroluminescence element. The illumination device includes a first and second substrate, wherein each of the photovoltaic element, the electroluminescence element and the electric energy storage element are located between the first and second substrates and wherein at least one of the first or second substrate comprises a flexible substrate. The illumination device further comprises sensor controlled electronics coupled to the device, wherein the sensor controlled electronics is configured to control the operation of the organic photovoltaic element, the electroluminescence element and the electric energy storage element.

### BACKGROUND

The invention relates generally to illumination devices, and more particularly, to flexible self-powered illumination devices that are configured to convert photon energy to electric energy for providing illumination.

Various illumination devices that utilize solar energy for illumination are known and are generally in use. Typically, such devices are useful for applications where sufficient electric power is not available or the cost of wiring from an electric power station to a desired location is substantially high. In certain applications, a solar cell and a display device are coupled to provide illumination by converting solar energy to electric power. However, designing and manufacturing such devices is difficult due to challenges in fabrication and integration of components.

Moreover, in certain applications such as, signage, consumer electronics and security sensors it may be desirable to manage and control the color and appearance of such illumination devices. Incorporation of functionalities to manage the color and appearances of such devices is a challenge due to costs and functionality issues. Further, integration of devices for converting the solar energy to electric power and for storing the generated electric power is difficult due to the challenges in the existing device fabrication process.

Accordingly, there is a need to provide an illumination device that is configured to convert solar energy to electric energy to power a lighting device for an application. It would also be advantageous to provide a device that is capable of managing the color appearance and the intensity of illumination from such a device.

### BRIEF DESCRIPTION

Briefly, in accordance with one aspect of the present invention an illumination device includes a photovoltaic element, wherein the photovoltaic element is configured to absorb photons of desired wavelengths and to convert the absorbed photon energy to electric energy and an electroluminescence element disposed adjacent to the photovoltaic element, wherein the electroluminescence element is configured to produce illumination at desired wavelengths, and wherein at least one of the photovoltaic element or the electroluminescence element comprises an organic material. The illumination device also includes an electric energy storage element coupled to the photovoltaic element and to the electroluminescence element, wherein the electric energy storage element is configured to store electric energy from the photovoltaic element and to power the electroluminescence element. The illumination device includes a first and second substrate, wherein each of the photovoltaic element, the electroluminescence element and the electric energy storage element are located between the first and second substrates and wherein at least one of the first or second substrate comprises a flexible substrate.

In accordance with another aspect of the present invention an illumination device includes a first flexible substrate, a second flexible substrate and an organic photovoltaic element disposed between the first and second flexible substrates. The illumination device also includes an organic light emitting device disposed between the first and second flexible substrates, wherein the organic light emitting device is disposed adjacent to the organic photovoltaic element.

### DRAWINGS

These and other features, aspects, and advantages of the present invention will become better understood when the following detailed description is read with reference to the accompanying drawings in which like characters represent like parts throughout the drawings, wherein:

FIG. 1 is a diagrammatical representation of an illumination device having a multiple layer structure in accordance with aspects of the present technique;

FIG. 2 is a diagrammatical representation of a single layer illumination device in accordance with aspects of the present technique;

FIG. 3 is a cross-sectional view of the components of a multiple layer illumination device, after the layers are coupled together;

FIG. 4 is a cross-sectional view of a single layer illumination device for providing illumination from one side in accordance with aspects of the present technique;

FIG. 5 is a cross-sectional view of a single layer illumination device for providing illumination from two sides in accordance with aspects of the present technique;

FIG. 6 is a cross-sectional view of another single layer illumination device for providing illumination from one side in accordance with aspects of the present technique;

FIG. 7 is a flow chart of an exemplary process for fabricating the illumination device of FIG. 1 according to one aspect of the invention;

FIG. 8 is a flow chart of an exemplary process for operating the illumination device of FIG. 1 according to one aspect of the invention; and

FIG. 9 is a diagrammatical representation of a sensor controlled illumination device according to one aspect of the invention.

### DETAILED DESCRIPTION

As further described below, a number of alternate embodiments for an illumination device in accordance with the present techniques are provided. Each illumination device includes a photovoltaic device, such as an organic photovoltaic element (OPV), an electroluminescence element, such as an organic light emitting device (OLED) and a storage element, such as a battery or capacitor. The elements are coupled between electrodes to form the illumination device. As will be appreciated, each of the elements may be contained within a single layer (i.e. between a top electrode and a bottom electrode). Alternatively, the illumination device may further include one or two additional substrates between the outer electrodes, such that the elements are contained within two or three layers. Regardless of the particular configuration, each of the present embodiments includes at least one organic element and at least one flexible substrate, as described further below.

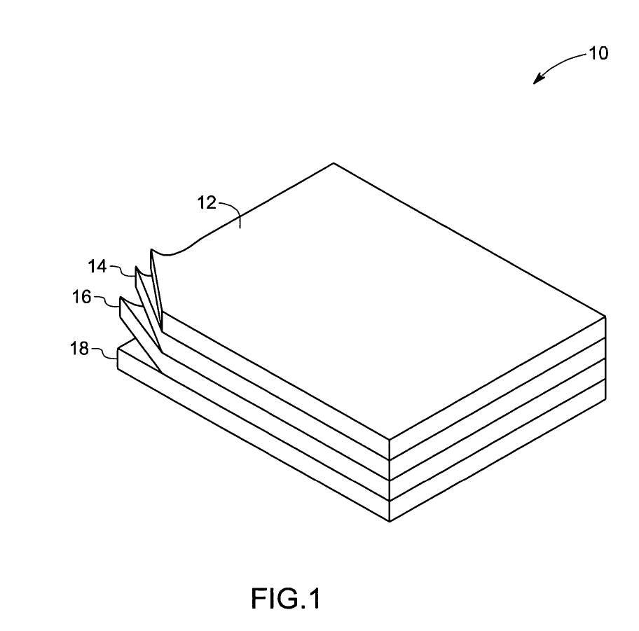

Referring now to the drawings, FIG. 1 illustrates a self-powered illumination device 10 having multiple layers in accordance with exemplary embodiments of the present technique. The illumination device 10 illustrated in FIG. 1 includes a photovoltaic device, such as an organic photovoltaic (OPV) cell 12 having a flexible substrate. The photovoltaic device may be an inorganic thin-film solar cellcell such as a-Si, CIGS, GaAs and CdTe or/and an organic solar cell of different types such as small molecular donor-acceptors, polymeric donor-acceptors, fulerenes-polymer heterojunction, dye-sensitized cells, or hybrid cells having organic materials and inorganic nano-materials, for example. In this embodiment, the organic photovoltaic cell 12 is configured to absorb photon energy and to convert the absorbed photon energy to electric energy. In certain embodiments, the organic photovoltaic cell 12 includes a flexible all-plastic organic cell. The illumination device 10 also includes a luminescence element, such as an organic light emitting device 14 disposed adjacent to the organic photovoltaic cell 12 for producing illumination at a desired wavelength. In accordance with embodiments of the present invention, at least one of the photovoltaic element and the luminescent element are organic devices.

Further, an electric storage element 16 is coupled to the organic photovoltaic cell 12 and to the organic light emitting device 14. In a presently contemplated configuration the electric storage element 16 stores electric energy from the organic photovoltaic cell 12 and provides the stored electric energy to power the organic light emitting device 14. Examples of electric storage element 16 include a capacitor and a rechargeable battery. In one embodiment, the electric storage element 16 comprises a lithium polymer battery. In addition, the illumination device 10 may include an optional back support substrate 18 for providing support to the illumination device 10.

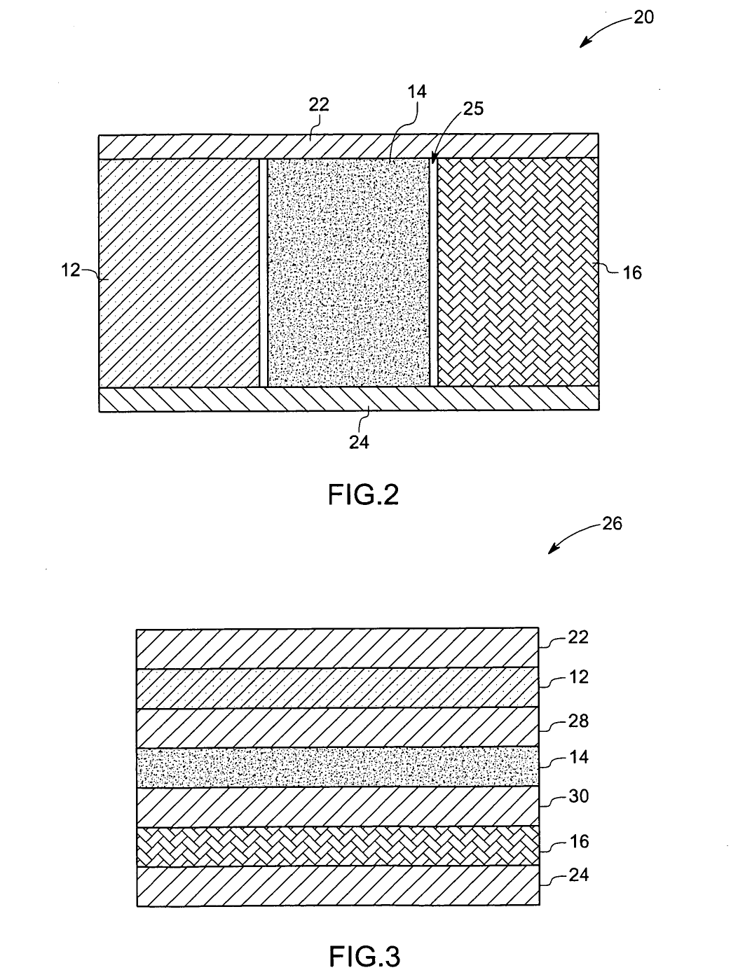

The organic photovoltaic cell 12, the organic light emitting device 14 and the electric storage element 16 may be disposed in configurations to produce a desired intensity and pattern of illumination. As will be appreciated, each of the organic electronic devices, such as the organic photovoltaic cell 12 and the organic light emitting device 14, and in one embodiment, even the electric storage element 16 generally includes a number of organic semiconductor layers disposed between two conductors or electrodes. As used herein, references to the organic photovoltaic cell 12, organic light emitting device 14 and electric storage element 16 generally refer to the electro-active material layers, and not the electrodes necessary to complete the devices. FIG. 2 illustrates an exemplary configuration 20 of the illumination device of FIG. 1. In a presently contemplated configuration, the active layers of the organic photovoltaic cell 12, the organic light emitting device 14 and the electric storage element 16 of the illumination device 20 are disposed between a first substrate 22 and a second substrate 24. In this embodiment, the first and second substrates 22 and 24 comprise conductive substrates that function as first and second electrodes. As will be appreciated by those skilled in the art, a non-conductive substrate with a conductive coating may be employed as the first and second substrates 22 and 24.

In the illustrated embodiment, each of the organic photovoltaic cell 12, the organic light emitting device 14 and the electric storage element 16 is disposed in a single layer between the first and second substrates 22 and 24. In certain embodiments, each of the first and second substrates 22 and 24 comprise a transparent substrate. Alternatively, one of the first and second substrates comprise an opaque substrate. The selection of the first and second substrates 22 and 24 may depend on a desired configuration or an application. Further, the organic photovoltaic cell 12, the organic light emitting device 14 and the electric storage elements may be separated by interconnects or an isolating material as represented by reference numeral 25.

In certain embodiments, the first and second substrates 22 and 24 may include one or more barrier coatings to form a top and bottom electrode of the illumination device 20. The barrier coating may comprise any suitable reaction or recombination products for reacting species. The barrier coating may be disposed at a thickness in the range of approximately 10 nm to about 10,000 nm, and preferably in the range of approximately 10 nm to about 1,000 nm. It is generally desirable to choose a coating thickness that does not impede the transmission of light through the flexible substrate (if a transparent substrate is desirable) such as a barrier coating that causes a reduction in light transmission of less than about 20%, and preferably less than about 5%. It is also desirable to choose a coating material and thickness that does not significantly reduce the substrate's flexibility, and whose properties do not significantly degrade with bending. The coating may be disposed by any suitable deposition techniques, such as plasma-enhanced chemical-vapor deposition (PECVD), radio-frequency plasma-enhanced chemical-vapor deposition (RFPECVD), expanding thermal-plasma chemical-vapor deposition (ETPCVD), reactive sputtering, electron-cyclodrawn-residence plasma-enhanced chemical-vapor deposition (ECRPECVD), inductively coupled plasma-enhanced chemical-vapor deposition (ICPECVD), sputter deposition, evaporation, atomic layer deposition (ALD), or combinations thereof.

The barrier coating may comprise organic, inorganic or ceramic materials, for instance. The materials are reaction or recombination products of reacting plasma species and are deposited onto the surface of the flexible substrates 22 and 24. Organic coating materials may comprise carbon, hydrogen, oxygen and optionally, other minor elements, such as sulfur, nitrogen, silicon, etc., depending on the types of reactants. Suitable reactants that result inorganic compositions in the coating are straight or branched alkanes, alkenes, alkynes, alcohols, aldehydes, ethers, alkylene oxides, aromatics, etc., having up to 15 carbon atoms. Inorganic and ceramic coating materials typically comprise oxide, nitride, carbide, boride, or combinations thereof of elements of Groups IIA, IIIA, IVA, VA, VIA, VIIA, IB, and IIB; metals of Groups IIIB, IVB, and VB, and rare-earth metals. For example, silicon carbide can be deposited onto a substrate by recombination of plasmas generated from silane (SiH₄) and an organic material, such as methane or xylene. Silicon oxycarbide can be deposited from plasmas generated from silane, methane, and oxygen or silane and propylene oxide. Silicon oxycarbide also can be deposited from plasmas generated from organosilicone precursors, such as tetraethoxysilane (TEOS), hexamethyldisiloxane (HMDSO), hexamethyldisilazane (HMDSN), or octamethylcyclotetrasiloxane (D4). Silicon nitride can be deposited from plasmas generated from silane and ammonia. Aluminum oxycarbonitride can be deposited from a plasma generated from a mixture of aluminum titrate and ammonia. Other combinations of reactants, such as metal oxides, metal nitrides, metal oxynitrides, silicon oxide, silicon nitride, silicon oxynitrides may be chosen to obtain a desired coating composition.

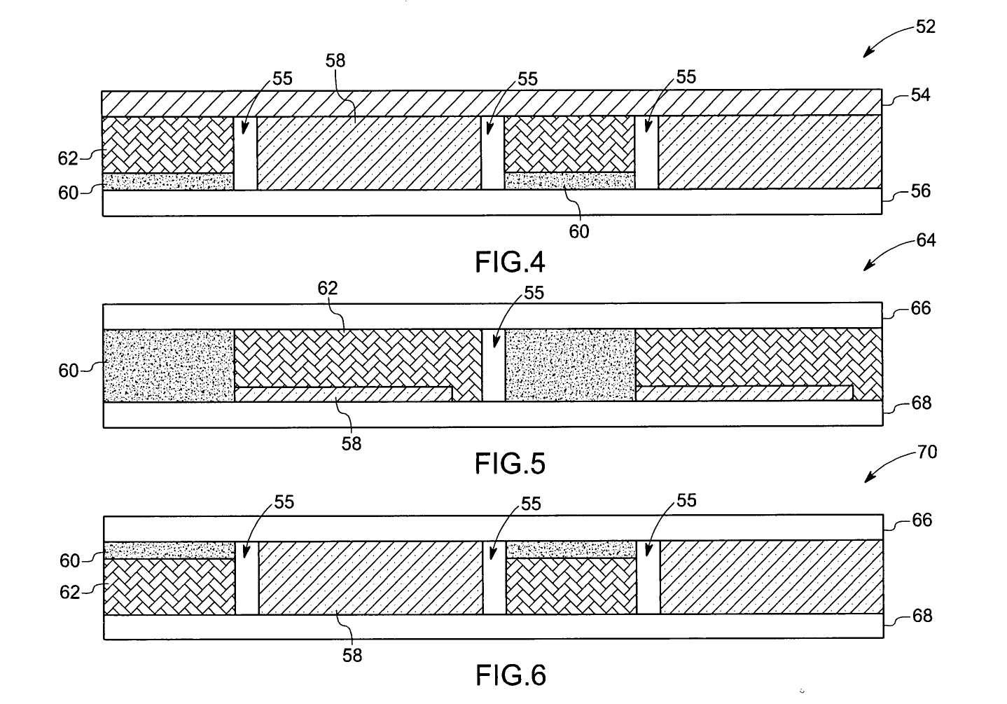

Further, the barrier coating may comprise hybrid organic/inorganic materials or multilayer organic/inorganic materials. The inorganic materials may be chosen from A-F elements and the organic materials may comprise acrylates, epoxies, epoxyamines, xylenes, siloxanes, silicones, etc. The choice of the particular reactants can be appreciated by those skilled in the art. Most metals may also be suitable for the barrier coating in applications where transparency of the flexible substrate (as in the substrate 54 of FIG. 4) is not required. As can be appreciated, the flexible substrates 22 and 24 may comprise a composition, which incorporates the barrier coating to provide a hermetic substrate.

Turning now to FIG. 3 a cross-sectional view of an exemplary multi-layered illumination device 26. Specifically, the illumination device 26 comprises three layers. In this embodiment, the illumination device 26 comprises first and second substrates 22 and 24, as well as intermediate substrates 28 and 30. The organic photovoltaic cell 12 may be coupled directly to the first substrate 22. In addition, the illumination device 20 includes a third substrate 28 disposed between the organic photovoltaic cell 12 and the organic light emitting device 14 and a fourth substrate 30 disposed between the organic light emitting device 14 and the electric energy storage device 16. In the present exemplary embodiment, the organic light emitting device 14 may be disposed on the third substrate 28 and the electric storage element may be disposed on the fourth substrate 30. As will be appreciated, the third and fourth substrates 28 and 30 include a conductive substrate.

In the present exemplary embodiments, each of the substrates 22, 24, 28 and 30 is a flexible substrate capable of facilitating roll-to-roll processing. The flexible substrates 22, 24, 28 and 30 are generally thin, having a thickness in the range of approximately 0.25-50.0 mils, and preferably in the range of approximately 0.5-10.0 mils. The term “flexible” generally means being capable of being bent into a shape having a radius of curvature of less than approximately 100 cm.

Each of the flexible substrates 22, 24, 28 and 30 may be dispensed from a roll, for example. Advantageously, implementing a roll of transparent film for each of the flexible substrates 22, 24, 28 and 30 enables the use of high-volume, low cost, reel-to-reel processing and fabrication of the illumination device 26. The roll of transparent film may have a width of 1 foot, for example, on which a number of components (e.g. the organic photovoltaic element 12, the organic light emitting device 14 and the electric storage element 16) may be fabricated and excised. Each of the flexible substrates 22, 24, 28 and 30 may comprise a single layer or may comprise a structure having a plurality of adjacent layers of different materials. By using rollable substrates, manufacturability of the illumination device 20 may be improved.

The flexible substrates 22, 24, 28 and 30 generally comprise any flexibly suitable polymeric material. For instance, the flexible substrate 22, 24, 28 and 30 may comprise polycarbonates, polyarylates, polyetherimides, polyethersulfones, polyimides, such as Kapton H or Kapton E (made by Dupont) or Upilex (made by UBE Industries, Ltd.), polynorbomenes, such as cyclic-olefins (COC), liquid crystal polymers (LCP), such as polyetheretherketone (PEEK), polyethylene terephthalate (PET), and polyethylene naphtalate (PEN).

In certain embodiments, the illumination device 26 may include multiple layers of the organic photovoltaic element 12 and their associated electrodes to manage the intensity and wavelength of the absorbed light through the organic photovoltaic element 12. Similarly, the organic light emitting device 14 may include a plurality of organic light emitting devices and their associated electrodes. The plurality of organic light emitting devices may be arranged in a pre-determined pattern to produce a desired pattern of illumination. In certain embodiments, the illumination device 26 may include multiple layers of electric storage elements 16.

In a presently contemplated configuration, the organic photovoltaic element 12, the organic light emitting device 14 and the electric storage element 16 are disposed onto respective substrates through a roll-to-roll printable process. For instance, each of the organic photovoltaic element 12, the organic light emitting device 14 and the electric storage element 16 may be disposed using printing drums (not shown).

Following the fabrication of each of the organic photovoltaic element 12, the organic light emitting device 14 and the electric storage element 16 on flexible substrates 22, 24, 28 and 30, these components are laminated together to form the flexible self-powered illumination device 26. As illustrated, the illumination device 26 comprises the organic photovoltaic element 12, the organic light emitting device 14 and the electric storage element 16 disposed between the first, second, third and fourth substrates 22, 24, 28 and 30. In certain embodiments, other configurations of the illumination device 26 with different arrangements of the organic photovoltaic element 12, the organic light emitting device 14 and the electric storage element 16 may be envisaged. For example, the organic photovoltaic element 12 may be disposed in a first layer and the organic light emitting device 14 and the electric storage element 16 may be disposed in a second layer. In another embodiment, the organic photovoltaic element 12 and the organic light emitting device 14 may be disposed in the first layer and the electric storage element 16 may be disposed in the second layer. Further, the components of the illumination device 26 may be arranged in various configurations for managing the color appearance, intensity of illumination and so forth as described below with reference to FIGS. 4-6.

By way of example, FIGS. 4-6 illustrate various configurations of the illumination device of FIG. 3. Referring first to FIG. 4 a cross-sectional view of a single layer illumination device 52 for providing illumination from one side is illustrated. In a presently contemplated configuration, the illumination device 52 includes a first flexible substrate 54 and a second flexible substrate 56, wherein the second flexible substrate 56 comprises a substantially transparent material. As used herein, “substantially transparent” refers to a material allowing a total transmission of at least about 50%, preferably at least about 80%, of visible light (i.e., having a wave length in the range from about 400 nm to about 700 nm). In this embodiment, the first and second substrates 54 and 56 function to provide first and second electrodes for the illumination device 52. In one embodiment, the second flexible substrate 56 comprises a polymer. Examples of polymer include a polycarbonate, a polyethylene terephthalate or a polyimide. The illumination device 52 also includes an organic photovoltaic element 58 disposed between the first and second flexible substrates 54 and 56. In the illustrated embodiment, the organic photovoltaic element 58 is directly coupled to each of the first and second flexible substrates 54 and 56. As previously described, the first and second flexible substrates 54 and 56 include a barrier coating such that they form front and back electrodes of the illumination device 52. In addition, an organic light emitting device 60 is disposed adjacent to the organic photovoltaic element 58 and is directly coupled to the second flexible substrate 56. In certain embodiments, the illumination device 52 comprises a plurality of organic light emitting devices 60 arranged in a pre-determined pattern to provide a desired pattern of illumination. In this embodiment, light emitted by the organic light emitting device 60 is transmitted through the second flexible substrate 56.

Moreover, an electric storage element 62 is disposed in an area adjacent to the organic light emitting device 60. The electric storage element 62 is configured to store energy from the organic photovoltaic element 58 and to power the organic light emitting device 60. In one embodiment, the electric storage element 62 is integrated with one of the organic light emitting device 60 or the organic photovoltaic element 58. In another embodiment, the electric storage element 62 is disposed proximate to the edges of the illumination device 52. In certain embodiments, the electric storage element 62 is disposed on a backside of the first flexible substrate 54. As will be appreciated, each of the active elements (i.e., the organic photovoltaic element 58, the organic light emitting device 60 and the electric storage element 62) may be coupled to one another through any suitable interconnect mechanism such as represented by reference numeral 55.

FIG. 5 illustrates a cross-sectional view of a single layer illumination device 64 for providing illumination from two sides. In the illustrated embodiment, the illumination device 64 includes first and second transparent electrodes 66 and 68. The transparent electrodes 66 and 68 may have any of the features previously described with reference to the transparent electrode 56 of FIG. 4. In the present exemplary embodiment illustrated in FIG. 5, the first and second transparent electrodes 66 and 68 comprise a polymer. Examples of polymer include a polycarbonate, a polyethylene terephthalate, a polyimide and so forth. In the present embodiment, the organic photovoltaic element 58 is disposed between the first and second transparent electrodes 66 and 68. The organic photovoltaic element 58 is directly coupled to the second transparent electrode 68. Further, the organic light emitting device 60 is disposed in an area adjacent to the organic photovoltaic element 58 between the first and second transparent electrodes 66 and 68. In this embodiment, the organic light emitting device 60 is coupled directly to the first and second transparent electrodes 66 and 68. In addition, the electric energy storage element 62 is disposed adjacent to the organic photovoltaic element 58. In this embodiment, the electric energy storage element 62 configured to store energy from the organic photovoltaic element 58 is disposed in an area such that the electric energy storage element 62 overlaps with the organic photovoltaic element 58.

It should be noted that, in the illumination device 64 the light emitted by the organic light emitting device 60 is transmitted through each of the first and second transparent electrodes 66 and 68 to provide illumination through each of the first and second transparent electrodes 66 and 68. Again, a plurality of organic light emitting devices 60 may be arranged in a pre-determined pattern to provide desired pattern of illumination through the illumination device 64.

FIG. 6 illustrates a cross-sectional view of another exemplary embodiment of a single layer illumination device 70 for providing illumination from one side. The illumination device 70 includes the first and second transparent electrodes 66 and 68. In the illustrated embodiment, the organic photovoltaic element 58 is disposed between the first and second transparent electrodes 66 and 68 and is directly coupled to the first and second transparent electrodes 66 and 68. In addition, the organic light emitting device 60 is disposed between the first transparent and second electrodes 66 and 68. In this embodiment, the organic light emitting device 60 is directly coupled to the first transparent electrode 66. It should be noted that, the light emitted from the organic light emitting device 60 is transmitted from the first transparent electrode 66. Further, the electric energy storage element 62 is disposed in an area adjacent to the organic light emitting device 60. As described above, the electric energy storage element 62 may be disposed proximate to edges of the illumination device 70.

As described above, FIGS. 4-6 illustrate a single layer structure where the organic light emitting device 60 and the organic photovoltaic element 58 are disposed in a single layer between the first and second electrodes. As will be appreciated by those skilled in the art, a variety of configurations of the illumination device may be envisaged having multiple layers, multiple illumination sides and so forth. For example, the illumination device 52 may have a configuration where the organic light emitting device 60 is disposed between first and second electrodes and the organic photovoltaic element 58 is disposed between third and fourth electrodes to form a two layer structure. In one embodiment, the organic light emitting device 60 and the organic photovoltaic element 58 comprise a common substrate. Further, the material utilized to form the electrodes may be selected based on desired illumination.

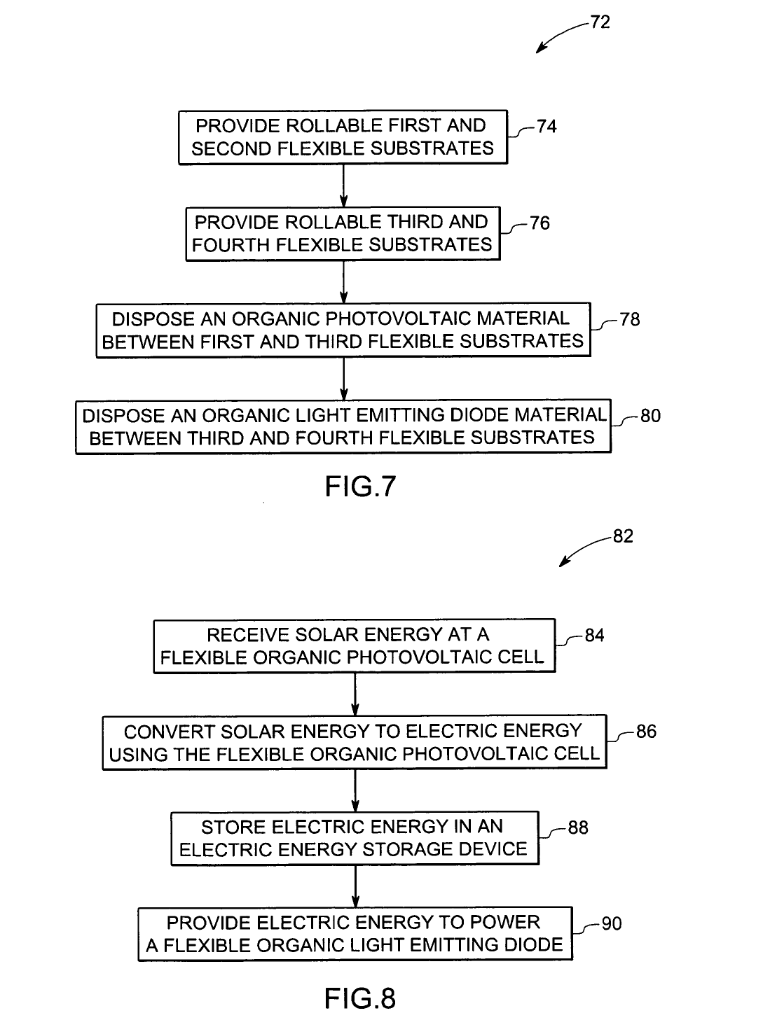

FIG. 7 illustrates an exemplary process 72 for fabricating the illumination device of FIGS. 1-3. The process 72 begins at step 74 with providing rollable first and second flexible substrates. In one embodiment, a barrier coating is provided on the first and second flexible substrates. The first and second flexible substrates may include flexible substrates comprising a substantially transparent material to provide illumination through the first and second flexible substrates. Alternatively, only one of the first and second flexible substrates may include a transparent material to produce illumination from one side of the illumination device. Next, as represented by step 76 third and fourth flexible substrates are provided. In this embodiment, the third and fourth flexible substrates include a coating of platinum disposed on the third and fourth flexible substrates.

At step 78, an organic photovoltaic material is disposed between the first and third flexible substrates. In certain embodiments, the organic photovoltaic material may be deposited on the first flexible substrate through a roll-to-roll fabrication process. Next, at step 80 an organic light emitting device material is disposed between the third and fourth flexible substrates. Again, the organic light emitting device may be deposited on the third flexible substrate through the roll-to-roll fabrication process. Further, an electric power storage material may be disposed between the second and fourth flexible substrates. Examples of such electric power storage material include a capacitor and a rechargeable battery. In certain embodiments, the electric power storage material may be integrated with the organic photovoltaic material or the organic light emitting device. In one embodiment, the electric power storage material may be deposited on the fourth flexible substrate through the roll-to-roll fabrication process. Finally, the first, third, fourth and second flexible substrates are laminated together, respectively, to form the self-powered illumination device illustrated in FIGS. 1-3. In certain embodiments, the organic photovoltaic device and the organic light emitting device may be fabricated independently and subsequently these devices may be laminated to form the illumination device. In this embodiment, the organic photovoltaic device may be fabricated with top and bottom substrates and similarly the organic light emitting device may be fabricated with top and bottom substrates. Subsequently, the organic photovoltaic device may be laminated with the organic light emitting device such that the top substrate of the organic light emitting device is laminated with the bottom surface of the organic photovoltaic device.

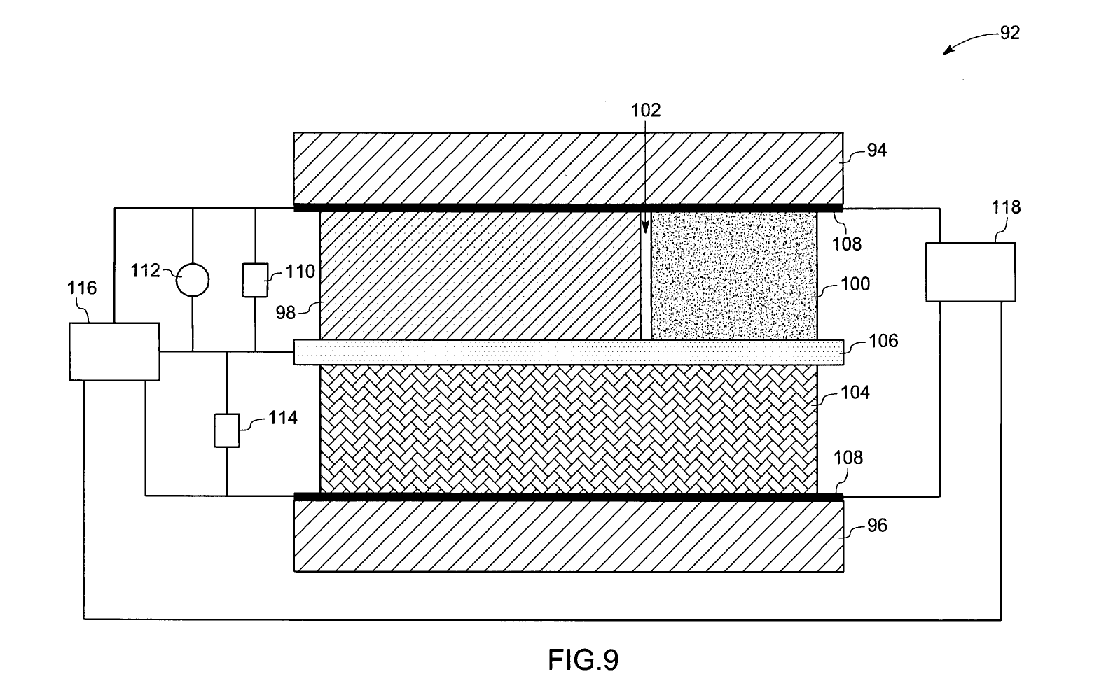

FIG. 8 illustrates an exemplary process 82 for operating various embodiments of the illumination devices fabricated in accordance with the presently described techniques. The process 82 begins with step 84 by receiving solar energy at a flexible organic photovoltaic cell. In certain embodiments, an intensity of the illumination may be controlled by controlled absorption of light through the flexible organic photovoltaic cell. Next, at step 86 the solar energy is converted to electric energy using the flexible organic photovoltaic cell. At step 88, the electric energy is stored in an electric energy storage device. As represented by step 90, the electric energy from the electric energy storage device is provided to a flexible organic light emitting device. In one embodiment, a desired pattern of illumination is provided through a plurality of organic light emitting devices arranged in a pre-determined pattern. Further, the operation of the illumination device described above may be controlled through sensor controlled electronics as will be described below with reference to FIG. 9.

Referring now to FIG. 9, a sensor controlled illumination device 92 having sensor controlled electronics is illustrated. For illustrative purposes, the exemplary embodiment provided to illustrate the sensor control mechanisms of the disclosed illumination device is a two layer illumination device. As will be appreciated, the control mechanisms may be utilized in any of the exemplary embodiments of the present invention. In the illustrated embodiment, the illumination device 92 includes first and second substrates 94 and 96. In this embodiment, the first substrate 94 comprises a transparent substrate. An organic photovoltaic element 98 is disposed between the first and second substrates 94 and 96. In addition, an organic light emitting device 100 is disposed adjacent to the organic photovoltaic element 98. The organic light emitting device 100 and the organic photovoltaic element 98 may be separated by interconnect materials or an isolating material as represented by reference numeral 102. An electric energy storage element 104 may be disposed adjacent to the organic photovoltaic element 98 and the organic light emitting device 100 and may be separated by a conductive substrate 106. In certain embodiments, a transparent conductive layer 108 may be disposed between the first and second substrates 94 and 96 and the organic photovoltaic element 98, the organic light emitting device 100 and the electric energy storage element 104.

In a presently contemplated configuration, a sensing device 110 may be integrated with the illumination device 92 to sense a parameter such as voltage that may be employed for controlling the operation of the illumination device 92. The sensing device 110 may be an external sensor or an imbedded sensor. In some embodiments, the organic photovoltaic element 98 may function as a light sensor. The sensed parameters through the sensing device 110 may then be transmitted to a sensor signal measurement and conditioning unit 112. Further, the illumination device 92 includes a battery monitoring and protection circuit 114 and a controller 116 coupled to the components of the illumination device 92. The controller 116 may include control electronics such as logic circuitry, timing circuitry, relays and program logic controls. Further, organic light emitting device switches or regulators 118 may be provided for controlling the operation of the organic light emitting device 100. Based upon the sensed parameter by the sensing device 110 the operation of the device 92 may be controlled. For example, in a condition where the sensed parameter represents a requirement of light then electric energy from the electric energy storage element 104 may be released to power the organic light emitting device 100. In certain embodiments, the illumination device 92 may be fully lighted or partially lighted based upon the energy stored in the electric energy storage device 104.

As will be appreciated by those skilled in the art, the present technique provides a self-powered illumination device that is configured to convert solar energy to electric energy to power a lighting device for an application. In addition, the present technique provides a mechanism of managing the color appearance and the intensity of illumination from such an illumination device. The various aspects of the technique described hereinabove have utility in various display, signage and lighting applications for example, dynamic camouflage, electronic 3D map, large area display, active safety guidance, consumer electronics, flexible display, security sensors and wireless controlled system among other applications.

While only certain features of the invention have been illustrated and described herein, many modifications and changes will occur to those skilled in the art. It is, therefore, to be understood that the appended claims are intended to cover all such modifications and changes as fall within the true spirit of the invention.

1. An illumination device comprising:
a photovoltaic element, wherein the photovoltaic element is configured to absorb photons of desired wavelengths and to convert the absorbed photon energy to electric energy;
an electroluminescence element disposed adjacent to the photovoltaic element, wherein the electroluminescence element is configured to produce illumination at desired wavelengths, and wherein at least one of the photovoltaic element or the electroluminescence element comprises an organic material;
an electric energy storage element coupled to the photovoltaic element and to the electroluminescence element, wherein the electric energy storage element is configured to store electric energy from the photovoltaic element and to power the electroluminescence element; and
a first and second substrate, wherein each of the photovoltaic element, the electroluminescence element and the electric energy storage element are located between the first and second substrates and wherein at least one of the first or second substrate comprises a flexible substrate.

2. The device of claim 1, wherein the photovoltaic element comprises an organic photovoltaic cell.

3. The device of claim 1, wherein the electroluminescence element comprises an organic light emitting device.

4. The device of claim 1, wherein the photovoltaic element and the electroluminescence element are disposed such that the device is configured to produce illumination from one side of the device.

5. The device of claim 1, wherein the photovoltaic element and the electroluminescence element are disposed such that the device is configured to produce illumination from two sides of the device.

6. The device of claim 1, wherein the photovoltaic element comprises small molecular donor-acceptors, or polymeric donor-acceptors, or fulerenes-polymer heterojunction, or dye-sensitized cells, or hybrid cells having organic materials and inorganic nano-materials.

7. The device of claim 1, wherein the electric energy storage element comprises one of a capacitor, a rechargeable battery or combinations thereof.

8. The device of claim 1, wherein the electric energy storage element is integrated with one of the electroluminescence element or the photovoltaic element.

9. The device of claim 1, wherein a plurality of organic light emitting devices are arranged in a pre-determined pattern to produce a desired pattern of illumination.

10. The device of claim 1, wherein the organic photovoltaic element is configured to absorb light within a pre-determined range of wavelength to manage color appearance of the device.

11. The device of claim 1, further comprising sensor controlled electronics coupled to the device, wherein the sensor controlled electronics is configured to control the operation of the organic photovoltaic element, the electroluminescence element and the electric energy storage element.

12. An illumination device comprising:
a first flexible substrate;
a second flexible substrate;
an organic photovoltaic element disposed between the first and second flexible substrates; and
an organic light emitting device disposed between the first and second flexible substrates, wherein the organic light emitting device is disposed adjacent to the organic photovoltaic element.

13. The device of claim 12, further comprising an electric energy storage element coupled to the organic photovoltaic cell and to the organic light emitting device.

14. The device of claim 12, wherein each of the organic photovoltaic element, the organic light emitting device and the electric energy storage element is disposed in a single layer between the first and second flexible substrates.

15. The device of claim 12, further comprising at least one substrate disposed between the first and second flexible substrates, and wherein the organic photovoltaic element, the organic light emitting device and the electric energy storage element are disposed in multiple layers between the first and second flexible substrates.

16. An illumination device comprising:
a first flexible substrate;
a second flexible substrate comprising a transparent material;
an organic photovoltaic element disposed between the first and second flexible substrates and coupled directly to each of the first and second flexible substrates; and
an organic light emitting device disposed adjacent to the organic photovoltaic element and coupled directly to the second flexible substrate.

17. The device of claim 16, further comprising an electric energy storage element disposed in an area adjacent to the organic light emitting device.

18. The device of claim 16, wherein the second flexible substrate comprises a polymer, or a metal foil, or a thin glass.

19. The device of claim 16, wherein the second flexible substrate comprises one of a polycarbonate, a polyethylene terephthalate or a polyimide.

20. The device of claim 16, wherein light emitted by the organic light emitting device is transmitted through the second flexible substrate.

21. An illumination device comprising:
a first transparent electrode;
a second transparent electrode;
an organic photovoltaic element disposed between the first and second transparent electrodes and directly coupled to the second transparent electrode; and
an organic light emitting device disposed in an area adjacent to the organic photovoltaic cell between the first and second transparent electrodes, wherein the organic light emitting device is coupled directly to the first and second transparent electrodes.

22. The device of claim 21, further comprising an electric energy storage element disposed adjacent to the organic photovoltaic element, wherein the electric energy storage element overlaps with the organic photovoltaic element.

23. The device of claim 21, wherein the first and second transparent electrodes comprise a polymer.

24. The device of claim 23, wherein the first and second transparent electrodes comprise one of a polycarbonate, a polyethylene terepthalate or a polyimide.

25. The device of claim 21, wherein light emitted by the organic light emitting device is transmitted through each of the first and second transparent electrodes to provide illumination through each of the first and second transparent electrodes.

26. An illumination device comprising:
a first transparent electrode;
a second transparent electrode;
an organic photovoltaic element disposed between the first and second transparent electrodes and directly coupled to the first and second transparent electrodes; and
an organic light emitting device disposed between the first and second transparent electrodes and directly coupled to the first transparent electrode, wherein light emitted by the organic light emitting device is transmitted through the first transparent electrode.

27. The device of claim 26, further comprising an electric storage element disposed in an area adjacent to the organic light emitting device.

28. The device of claim 26, wherein the first and second transparent electrodes comprise a polymer substrate.
